(19) United States
(12) Patent Application Publication
(10) Pub. No.: US 2006/0158201 A1
(43) Pub. Date: Jul. 20, 2006

(54) Semiconductor integrated circuit device and method for testing the same

(75) Inventors: Satoshi Sobue, Nukata-gun (JP); Tomohisa Yamamoto, Hoi-gun (JP); Shunji Kamei, Nagoya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/283,907

(22) Filed: Nov. 22, 2005

(30) Foreign Application Priority Data
Jan. 19, 2005 (JP) 2005-011636

(51) Int. Cl. G01R 27/26

(52) U.S. Cl. 324/678

(57) ABSTRACT

A semiconductor integrated circuit device includes a semiconductor layer formed on a support substrate so as to be insulated from the support substrate; plural circuit blocks formed in the semiconductor layer so as to be insulated from one another; and at least one pair of power supply terminals provided in connection with each of the circuit blocks to supply power to the respective circuit block. The circuit blocks operate as a whole while connected together in series by successively connecting the power supply terminals of different circuit blocks to one another, and also each of the circuit blocks can operate independently under a state that a voltage is applied between the pair of power supply terminals.

### CROSS REFERENCE TO RELATED APPLICATION

This application is based upon, claims the benefit of priority of, and incorporates by reference the contents of, Japanese Patent Application No. 2005-11636 filed on Jan. 19, 2005.

### TECHNICAL FIELD

The technical field relates to an insulating separation type semiconductor integrated circuit device and a method of testing the same.

### BACKGROUND

A battery pack used as a battery for an electric vehicle (EV) or a hybrid vehicle (HV) requires a high voltage of about 100V to 400V. Therefore, it is conventionally designed as many secondary batteries (cells) are connected to one another in series. For example, in the case of a battery pack of 300V, 150 cells are connected to one another in series for a lead battery (about 2V/cell), 250 cells are connected to one another in series for a nickel hydride battery (1.2V/cell) and 80 cells are connected to one another in series for a lithium ion battery (3.6V/cell).

The secondary battery, particularly, the lithium ion battery is susceptible to over-charging or over-discharging, and thus it might be remarkably reduced in capacity or heated if it is not used in a predetermined restricted voltage range. Therefore, when a battery pack is used, constant voltage charging control is performed so that the cell voltage of the battery pack is within a voltage range determined by predetermined upper and lower limit voltages, and also an over-charging/over-discharging detecting circuit is used to detect whether the cell voltage is out of the above restricted voltage range. Furthermore, a cell voltage equalizing circuit is used to reduce the dispersion in cell voltage caused by the dispersion in charging state (SOC: State Of Charge) among the cells constituting the battery pack (see JP-A-2004-080909).

When the over-charging/over-discharging detecting circuit and the cell voltage equalizing circuit are constructed in the form of IC, for example, each set of eight cells is constructed as one IC in consideration of the withstanding voltage, etc. When a lithium ion battery is used, a voltage applied to an IC is normally set to 28.8V (=3.6V×8), and at least a test voltage which is not less than the above voltage is needed to carry out a burn-in test after packaging. FIG. 4A shows a state where the burn-in test is performed by applying a test voltage VBI to IC 101, and FIG. 4B shows a state where IC 101 is used while connected to a battery pack 102.

However, the test voltage VBI prepared in a burn-in test device 103 is normally set to about 20V, and it is generally difficult to achieve a test voltage higher than the above voltage under the present condition. When the above IC 101 is tested by using the burn-in test device 103, there is a disadvantage in that it is impossible to apply a sufficient test voltage and thus the test time is lengthened.

### SUMMARY

In view of the foregoing situation, it is an object to provide a semiconductor integrated circuit device that can execute a sufficient voltage applying test by using a test voltage whose magnitude is limited, and a method of testing the semiconductor integrated circuit device.

In order to attain the above object, according to a first aspect, a circuit formed as a semiconductor integrated circuit device (hereinafter referred to as an overall circuit) is constructed to be divided into plural circuit blocks that are allowed to be connected to one another in series and electrically insulated from one another. In connection with each of these circuit blocks, the semiconductor integrated circuit device has at least one pair of power supply terminals for supplying power to each circuit block. The circuit elements constituting each circuit block is connected between power supply lines connected to the power supply terminals. When a voltage is applied between the power supply terminals, the circuit block concerned can operate independently of the other circuit blocks by itself.

When the semiconductor integrated circuit device described above is used, the power supply terminals of the respective circuit may be successively connected to one another to construct and operate the overall circuit. Furthermore, when a voltage is applied to this semiconductor integrated circuit device to test the semiconductor integrated circuit device, a voltage may be applied between the power supply terminals of the respective circuit blocks to operate each circuit block independently. According to the first aspect, the test can be performed by using a lower voltage as compared with a voltage applying test that is performed on the overall semiconductor integrated circuit device as a whole, and thus the degree of freedom of choice for the test device is increased and the test time in the burn-in test can be shortened. Furthermore, when an IC tester is used, the voltage can be measured by using a lower voltage measurement range, so that the voltage measurement precision can be enhanced.

According to a second aspect, the semiconductor integrated circuit device described above may have at least one of a cell voltage equalizing circuit of a battery pack for equalizing the voltages of the respective cells and a cell over-charging/over-discharging detecting circuit of a battery pack for detecting an excessive charging/discharging state of each cell. Since the battery pack is constructed by connecting plural secondary cells to one another in series, the voltage is increased, and a test voltage needed for the voltage applying test of the semiconductor integrated circuit device is liable to be short. According to the second aspect, the test can be performed while the cell voltage is separated every circuit block constructed as a basic unit, and thus the test can be performed under such a situation that a high test voltage cannot be achieved.

According to a third aspect, in the above semiconductor integrated circuit device, the respective circuit blocks are connected to one another in parallel by commonly connecting the power supply terminals of the respective circuit blocks, and the test voltage is applied between the commonly connected power supply terminals, so that the overall circuit of the semiconductor integrated circuit device can be tested at one time, and the test time can be shortened.

According to a fourth aspect, in the semiconductor integrated circuit device described above, the in-series connection numbers of the cell voltage equalizing circuits or the cell over-charging/discharging detecting circuits are set to be equal between the respective circuit blocks, so that the test voltage can be effectively reduced by a smaller divisional number (circuit block number).

According to a fifth aspect, in the semiconductor integrated circuit device described above, the test time of the burn-in test can be shortened. Furthermore, the voltage measurement precision can be enhanced in the test based on the IC tester.

### BRIEF DESCRIPTION OF THE DRAWINGS

FIG. 1 shows a diagram of a circuit construction of a first embodiment when a burn-in test of an IC is performed;

FIG. 2 is a diagram showing a circuit construction when the IC is used while connected to a battery pack;

FIG. 3 is a longitudinally-sectional view of IC; and

FIG. 4A is a diagram showing a state where a burn-in test is performed on IC, and FIG. 4B is a state where IC is used while connected to a battery pack.

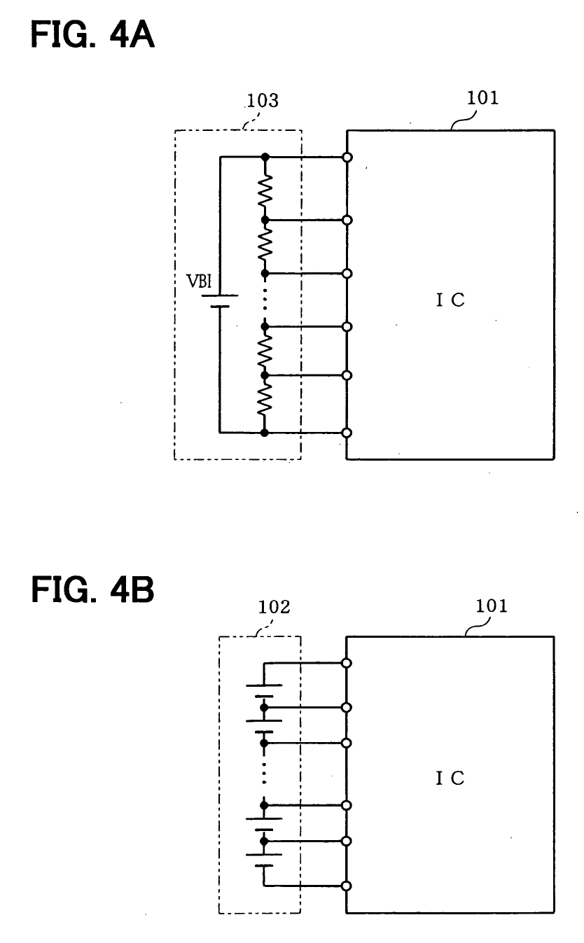

### DETAILED DESCRIPTION OF THE PREFERRED EMBODIMENTS

Preferred embodiments will be described hereunder with reference to the accompanying drawings.

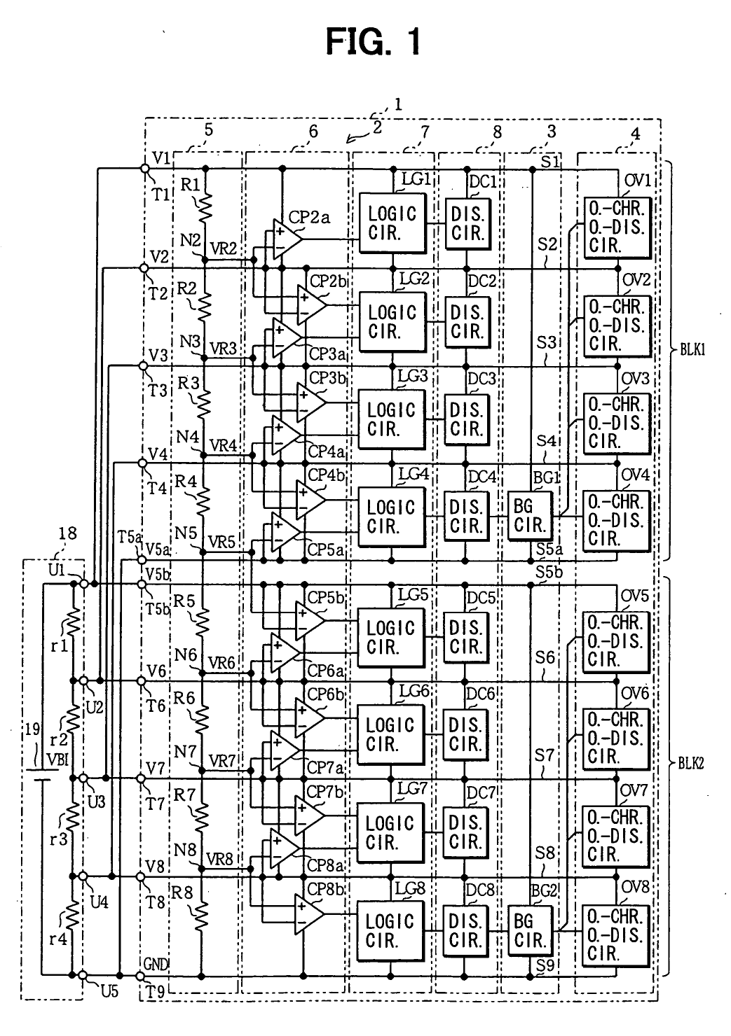

An embodiment exemplified in a monitoring IC (semiconductor integrated circuit device) for a battery pack is applied will be described with reference to FIGS. 1 to 3.

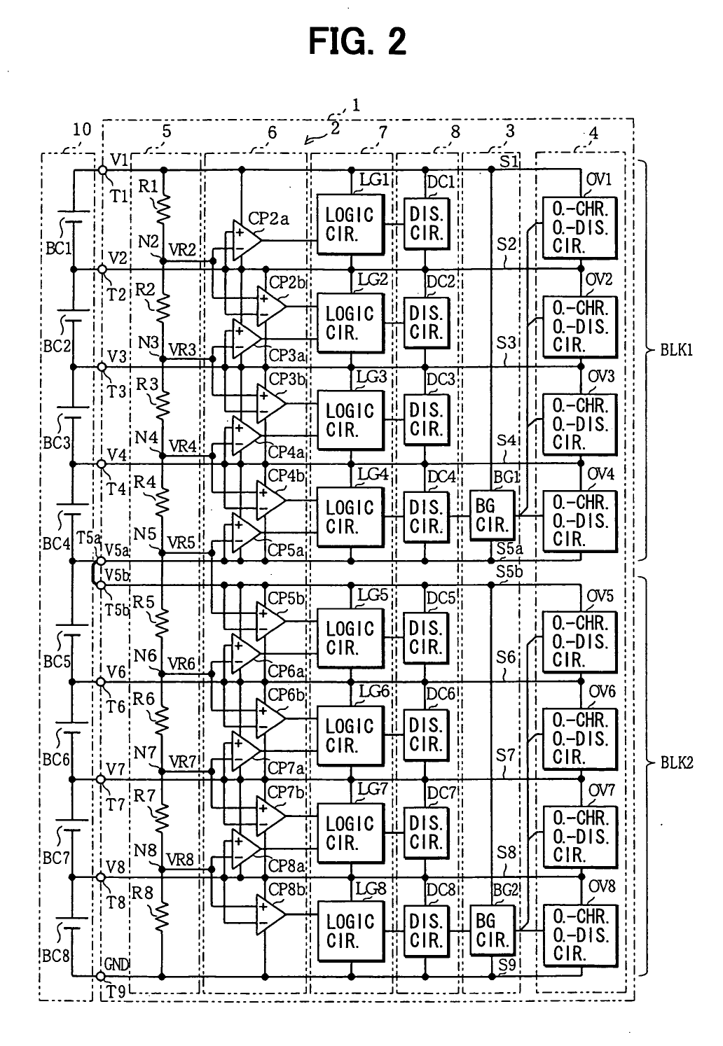

FIG. 1 shows a circuit construction when a burn-in test of the IC is performed, and FIG. 2 shows a circuit construction when the IC is used while connected to a battery pack. A battery pack 10 which is a control target of the IC 1 is a secondary cell used as a battery of an electric vehicle (EV) or hybrid electric vehicle (HV), and it is constructed by a lithium-ion battery, for example. The battery pack 10 is constructed by plural cell groups connected in series, and each cell group is constructed by eight cells BC1 to BC8 connected in series. The terminals T1 to T9 of IC 1 serve as connection terminals to the battery pack 10, and a cell BCn (n=1, 2, . . . , 8) is connected between a terminal Tn and a terminal Tn+1 under a normally used state as shown in FIG. 2.

IC 1 is equipped with an equalizing circuit(s) 2, a constant voltage generating circuit 3 and an over-charging/over-discharging detecting circuit(s) 4, and the equalizing circuit 2 is constructed by a reference voltage generating circuit 5, a comparison circuit portion 6, a discharge control circuit portion 7 and a discharging circuit portion 8. Under a state that an IG switch (containing a main power supply switch) is turned off, that is, during a time period when a vehicle is not used in the nighttime or the like, the respective voltages of the cells BC1 to BC8 constituting the battery pack 10 are subjected to discharge control by each equalizing circuit 2 (corresponding to a cell voltage equalizing circuit) so that these voltages are coincident with the lowest voltage among the voltages of the cells BC1 to BC8, thereby equalizing the dispersion of the charging states (SOC) of the cells BC1 to BC8. The over-charging/over-discharging detecting circuit 4 (corresponding to a cell over-charging/over-discharging detecting circuit) detects the over-charging state or over-discharging state of the cells BC1 to BC8 under the state where the IG switch of the vehicle is turned on, and outputs a detection signal (diagnostic signal).

IC 1 is constructed so as to be separated into two circuit blocks BLK1 and BLK2 which are electrically insulated from each other except for the reference voltage generating circuit 5. The circuit block BLK1 is the circuit portion corresponding to the cells BC1 to BC4, and it is formed between a power supply line S1 connected to a terminal T1 and a power supply line S5a connected to a terminal T5a. The circuit block BLK2 is the circuit portion corresponding to the cells BC5 to BC8, and it is formed between a power supply line S5b connected to a terminal T5b and a power supply line S9 connected to a terminal T9.

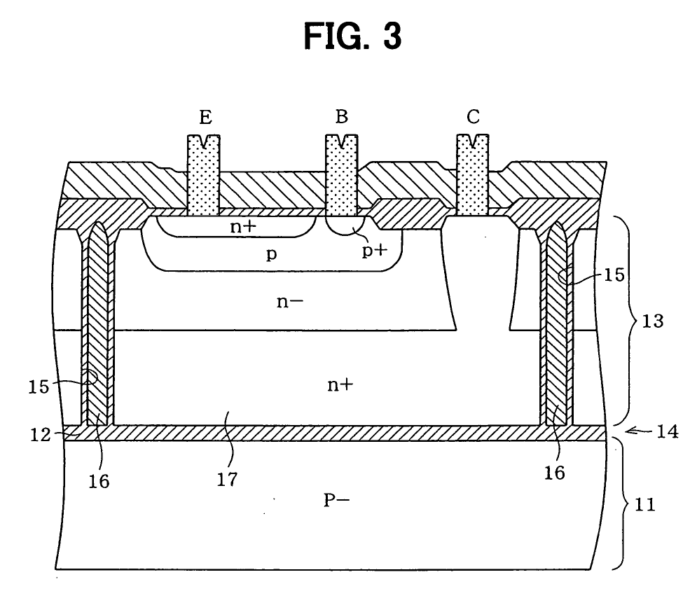

As shown in FIG. 3, IC 1 is constructed by using an SOI (Silicon On Insulator) substrate 14 including a monocrystal silicon layer 13 (corresponding to a semiconductor layer) formed on a monocrystal silicon substrate 11 (corresponding to a support substrate) through an insulating separation layer 12 formed of silicon oxide film. A groove 15 extending to the insulating separation layer 12 is formed in the SOI substrate 14, oxide film is formed on the groove 15 and then polysilicon 16 is embedded in the groove 15, thereby forming an element forming area 17. The circuit blocks BLK1 and BLK2 are formed in different element forming areas 17, whereby the circuit blocks BLK1 and BLK2 are insulated from each other. FIG. 3 shows a bipolar transistor formed by using a well-known manufacturing technique.

The reference voltage generating circuit 5 is constructed by eight resistors R1 to R8 connected to one another in series between the terminals T1 and T9. Reference voltages VR2, VR3, . . . , VR8 under the state that all the cells BC1 to BC8 are equalized to one another are generated at the connection node N2 between resistors R1 and R2, the connection node N3 between resistors R2 and R3, . . . , the connection node N8 between resistors R7 and R8. All the cells BC1 to BC8 have the same voltage specification, and all the resistors R1 to R8 are set to the same resistance value.

The comparison circuit portion 6 is constructed by comparators CP2a and CP2b for comparing the voltage V2 of the power supply line S2 and the reference voltage VR2 of the node N2, . . . , a comparator CP5a for comparing the voltage V5a of the power supply line S5a and the reference voltage VR5 of the node N5, a comparator CP5b for comparing the voltage V5b of the power supply line S5b and the reference voltage VR5 of the node N5, . . . , and comparators CP8a and CP8b for comparing the voltage V8 of the terminal T8 and the reference voltage VR8 of the node N8. The comparators CP2a, CP2b, . . . , CP5a of the above comparators are supplied with power from the power supply lines S1 to S5a and operated, and they belong to the circuit block BLK1. Furthermore, the comparators CP5b, CP6a, . . . , CP8b are supplied with power from the power supply lines S5b to S8 and operated, and they belong to the circuit block BLK2.

The discharge control circuit portion 7 outputs a discharge control signal to the discharging circuit portion 8 on the basis of the output signal of the comparing circuit portion 6, and it is constructed by logic circuits LG1 to LG8. The logic circuits LG1 to LG4 are designed so that they are supplied with power from the power supply lines S1 to S5a and operated, and they belong to the circuit block BLK1. Furthermore, the logic circuits LG5 to LG8 are designed so that they are supplied with power from the power supply lines S5b to S8 and operated, and they belong to the circuit block BLK2.

The discharging circuit portion 8 is constructed by a discharging circuit DC1 connected between the power supply lines S1 and S2, . . . , a discharging circuit DC4 connected between the power supply lines S4 and S5a, a discharging circuit DC5 connected between the power supply lines S5b and S6, . . . , and a discharging circuit DC8 connected between the power supply lines S8 and S9. The discharging circuit DC1 to DC4 belong to the circuit block BLK1, and the discharging circuit DC5 to DC8 belong to the circuit block BLK2. Each of these discharging circuits DC1 to DC8 serves as a switch circuit designed so that a transistor is constructed as a discharging route, and it turns on or off the discharging route on the basis of the discharge control signal from the discharge control circuit portion 7.

The constant voltage generating circuit 3 is constructed by a band gap reference BG1 that is supplied with a voltage between the power supply lines S1 and S5a and outputs a constant voltage, and a band gap reference BG2 that is supplied with a voltage between the power supply lines S5b and S8 and outputs a constant voltage. These band gap references BG1 and BG2 belong to the circuit blocks BLK1 and BLK2.

The over-charging/over-discharging detecting circuit 4 is constructed by a detecting circuit OV1 connected between the power supply lines S1 and S2, . . . , a detecting circuit OV4 connected between the power supply lines S4 and S5a, a detecting circuit OV5 connected between the power supply lines S5b and S6, . . . , and a detecting circuit OV8 connected between the power supply lines S8 and S9. The detecting circuits OV1 to OV4 belong to the circuit block BLK1, and operates by using the constant voltage of the band gap reference BG1. The detecting circuits OV5 to OV8 belong to the circuit block BLK2, and operates by using the constant voltage of the band gap reference BG2.

In order to guarantee the quality and the reliability for this IC 1, a screening work for removing articles which may induce time-lapse deterioration or a failure caused by stress is performed before shipped as products. A burn-in test device 18 shown in FIG. 1 is used to carry out the screening work, and it is constructed by a power source 19 for supplying a test voltage VBI (for example, 20V), resistors r1 to r4 for dividing the voltage, a temperature control device (not shown), etc. The burn-in test device 18 applies a rating or higher test voltage VBI to IC 1 under a temperature condition more severe than an actual use condition to operate the IC 1, whereby temperature and voltage stresses are applied to the IC 1 concerned to promote characteristic deterioration caused by latent defects.

Next, the action and effect of this embodiment will be described.

Under the normal use state that IC 1 is made to monitor the battery pack 10, the terminals T5a and T5b are connected to each other at the outside of IC 1 as shown in FIG. 2, whereby the circuit blocks BLK1 and BLK2 are connected to each other in series (so that the power source voltage is applied). In this case, the equalizing circuits 2 of IC 1 operate to equalize the respective voltages of the cells BC1 to BC8 constituting the battery pack 10, and the over-charging/over-discharging detecting circuit 4 detects the over-charging state or over-discharging state of the cells BC1 to BC8.

Under the burn-in test state of IC 1, the terminals T1, T2, T3, T4, T5a provided in connection with the circuit block BLK1 of IC 1 and the terminals T5b, T6, T7, T8 and T9 provided in connection with the circuit block BLK2 are connected to one another as shown in FIG. 1, thereby connecting the circuit blocks BLK1 and BLK2 in parallel. The output terminals U1, U2, U3, U4 and U5 of the burn-in test device 18 are connected to the respective commonly connected terminals, and the test voltage VBI is applied to IC 1 under a predetermined temperature test atmosphere. The IC 1 has an insulating separation structure, and thus the circuit blocks BLK1 and BLK2 are supplied with the test voltage VBI and the divided voltage thereof respectively, and operate independently of each other.

At this time, the test voltage VBI is applied between the terminals T1 and T5a of IC 1 and between the terminals T5b and T9, that is, applied to each circuit group corresponding to the four cells of the battery pack 10. According to the burn-in test of this embodiment, for example when the voltage VBI of the power source 19 is set to 20V and the cell voltage of the battery pack 10 is set in the range from 3V to 4.1V, a test voltage of 5V (=20V/4) can be applied in connection with the cell voltage, and sufficient acceleration test can be performed while the circuit blocks BLK1 and BLK2, that is, the whole IC are operated.

On the other hand, in the conventional burn-in test, the test voltage VBI is applied between the terminals T1 and T9 of IC 1, that is, to a circuit group corresponding to eight cells of the battery pack 10, and thus only the test voltage of 2.5V (=20V/8) can be applied in connection with the cell voltage.

As described above, IC 1 of this embodiment is constructed so as to be divided to the two circuit blocks BLK1 and BLK2 that are designed to be connected to each other in series and also electrically insulated from each other. Therefore, the test voltage VBI of the burn-in test device 18 can be applied to each of the circuit blocks BLK1 and BLK2 in the burn-in test. Here, each of the circuit blocks BLK1 and BLK2 is designed so that the equalizing circuits 2, the over-charging/discharging detecting circuits 4 of four cells are connected to one another in series. This equivalently means that the double test voltage (2×VBI) can be effectively usable.

Accordingly, the double test voltage 2×VBI (40V) can be substantially applied to the whole IC 1 by using the test voltage VBI (20V), and thus a sufficient stress can be given to the IC 1. Furthermore, the circuit blocks BLK1 and BLK2 are connected to each other in parallel and the test voltage VBI can be applied to the circuit blocks at a time, so that the test time of the burn-in test can be prevented from increasing and rather the test time can be shortened because the test voltage is substantially doubled.

The battery pack 10 is constructed so that the eight cells BC1 to BC8 are connected to one another in series. Therefore, there has been such a situation that the voltage is increased and the test voltage VBI needed for the burn-in test of the monitoring IC 1 is liable to be short. However, according to this embodiment, the burn-in test can be performed by using even a burn-in test device 18 having only a test voltage VBI lower than the voltage of the battery pack 10. Furthermore, when the voltage of each part of IC 1 is measured by using a voltage measurement device in the burn-in test, the voltage can be measured by using a lower voltage measurement range, and thus the voltage measurement precision can be enhanced.

The present invention is not limited to the embodiments described above with reference to the drawings. The following modifications or expansion can be made, for example.

IC 1 is constructed as an in-series circuit of the two circuit blocks BLK1 and BLK2, however, it may be constructed as an in-series circuit of three or more circuit blocks. Accordingly, the effective test voltage applied to IC 1 can be further increased. In this case, it is preferable that the in-series connection number of the equalizing circuits 2, the over-charging/over-discharging detecting circuits 4 is equal between the circuit blocks.

The embodiment has been described by using the monitoring IC for the battery pack 10 as an example, however, IC having other functions may be used. In the above described IC 1, five power supply terminals are provided in connection with each circuit block in consideration of the properties thereof, however, any construction may be adopted for each circuit block insofar as each circuit block has at least one pair of power supply terminals and the circuit block concerned can operate under the state that a voltage is applied between the power supply terminals.

The reference voltage generating circuit 5 of this embodiment is not separated to the circuit blocks BLK1 and BLK2, and thus the test voltage VBI is applied to the whole in-series circuit from the resistor R1 to the resistor R8. When IC has extra terminals, the resistors R4 and R5 are not connected to each other in IC, but they may be connected to each other through the terminals of IC at the outside of IC. With this construction, the double test voltage 2×VBI can be effectively used for the reference voltage generating circuit 5.

The circuit blocks BLK1 and BLK2 are connected to each other in parallel and the test voltage VBI is applied to them at a time to carry out the test. However, the test voltage VBI may be separately applied to each of the circuit blocks to carry out the test. The test method described above is not limited to the burn-in test after packaging, but it may be applied to a wafer (chip) burn-in test, a test (probe test) using an IC tester or the like.

What is claimed is:

1. A semiconductor integrated circuit device comprising:
a semiconductor layer formed on a support substrate so as to be insulated from the support substrate;
plural circuit blocks formed in the semiconductor layer so as to be insulated from one another; and
at least one pair of power supply terminals provided in connection with each of the circuit blocks to supply power to the respective circuit block, wherein the circuit blocks can operate as a whole while connected together in series by successively connecting the power supply terminals of different circuit blocks to one another, and also each of the circuit blocks can operate independently under a state that a voltage is applied between the pair of power supply terminals.

2. The semiconductor integrated circuit device according to claim 1, wherein each circuit block has at least one of a cell voltage equalizing circuit for equalizing the voltages of respective cells of a battery package constructed by connecting plural secondary cells to one another in series and a cell over-charging/over-discharging equalizing circuit for detecting an excessively charging/discharging state of each cell of the battery pack.

3. A method of testing a semiconductor integrated circuit device by applying a voltage to a power supply terminal, the semiconductor integrated circuit device comprising: a semiconductor layer formed on a support substrate so as to be insulated from the support substrate; plural circuit blocks formed in the semiconductor layer so as to be insulated from one another; and at least one pair of power supply terminals provided in connection with each of the circuit blocks to supply power to the circuit block concerned, wherein when the semiconductor integrated circuit device is in use, the power supply terminals of the different circuit blocks are successively connected to one another to make the circuit blocks operate as a whole under a state that the circuit blocks are connected to one another in series, and when the semiconductor integrated circuit device is under a test state, a test voltage is applied between the power supply terminals of the respective circuit blocks.

4. The semiconductor integrated circuit device testing method according to claim 3, wherein under the test state of the semiconductor integrated circuit device, the power supply terminals of the respective circuit blocks are commonly connected to each other to connect the circuit blocks in parallel, and a voltage is applied between the commonly-connected power supply terminals.

5. The semiconductor integrated circuit device testing method according to claim 3, wherein the semiconductor integrated circuit device has at least one of a cell voltage equalizing circuit for equalizing the voltages of respective cells of a battery package constructed by connecting plural secondary cells to one another in series and a cell over-charging/over-discharging equalizing circuit for detecting an excessively charging/discharging state of each cell of the battery pack, and each circuit block is constructed by connecting in series a predetermined number of cell voltage equalizing circuits or cell over-charging/over-discharging detecting circuits each of which is provided in connection with each cell.

6. The semiconductor integrated circuit device test method according to claim 5, wherein the in-series connection number of cell voltage equalizing circuits or the cell over-discharging/over-charging detecting circuits are set to be equal between the respective circuit blocks.

7. The semiconductor integrated circuit device testing method according to claim 3, wherein a burn-in test or a test using an IC tester is executed.

8. The semiconductor integrated circuit device testing method according to claim 4, wherein the semiconductor integrated circuit device has at least one of a cell voltage equalizing circuit for equalizing the voltages of respective cells of a battery package constructed by connecting plural secondary cells to one another in series and a cell over-charging/over-discharging equalizing circuit for detecting an excessively charging/discharging state of each cell of the battery pack, and each circuit block is constructed by connecting in series a predetermined number of cell voltage equalizing circuits or cell over-charging/over-discharging detecting circuits each of which is provided in connection with each cell.
